(19) United States
(12) Patent Application Publication
(10) Pub. No.: US 2021/0307170 A1
(43) Pub. Date: Sep. 30, 2021

(54) SENSORY ARRAY FOR USE WITH ARTIFICIAL SKIN AND ARTIFICIAL SKIN WITH SENSORY ARRAY, USEFUL IN ROBOTICS

(71) Applicant: SANCTUARY COGNITIVE SYSTEMS CORPORATION, Vancouver (CA)

(72) Inventors: Kevin Jiaming Wu, Vancouver (CA); Connor Richard Shannon, Vancouver (CA)

(21) Appl. No.: 17/217,650

(22) Filed: Mar. 30, 2021

Related U.S. Application Data
(60) Provisional application No. 63/001,755, filed on Mar. 30, 2020.

(51) Int. Cl. H05K 1/14; G01D 11/24

(52) U.S. Cl. CPC H05K 1/142; H05K 1/147; H05K 2201/10151; H05K 2201/058; G01D 11/24

(57) ABSTRACT

A flexible modular skin sensor array can cover any surface of a robot. The skin sensor array includes a flexible mesh and a set of modular sensor panels that attached to the mesh. The skin sensor array underlies or is molded inside a skin membrane (e.g., silicone), and can flex and stretch with the skin. Each modular sensor panel has a communications chip and one or more sensors. A master controller provides communications with the modular sensor panels through a shared bus. Modular sensor panels can fail without affecting the network. The flexible mesh and modular sensor panels may be made of flexible PCB, to accommodate movement of the skin. A set of convoluted bridges connect locations at which the modular sensor panels attach, allowing for flexing and stretching without tearing of the flexible mesh. The redundancy allows some of the connection leads to fail without affecting communications.

### TECHNICAL FIELD

The present disclosure generally relates to sensor arrays for use with artificial skin (e.g., silicone membrane) and artificial skin with sensory arrays, which may be used as a skin or interface for a robot, for instance a robot with a humanoid appearance.

### BACKGROUND

### Description of the Related Art

Various types of sensors are used to measure or otherwise sense various physical characteristics. For example, force sensors (e.g. piezoelectric transducers, load cells) sense a force applied to a portion of the force sensor. Also for example, capacitive sensors sense a capacitance or change in capacitance applied to a portion of the capacitive sensor, which may for example be used to detect a tactile input such as touch by a human digit. Also for example, inertial sensors (e.g., an inertial measurement sensors, single or multi-axis accelerometers) senses inertial forces applied to at least a portion of the inertial sensor. Also for example, temperature sensors (e.g., thermocouples) sense a temperature proximate at least a portion of the temperature sensor.

Robots are becoming increasingly common in commercial use. Some robots are designed to interact with humans, and such robots typically employ a user interface which allows the robot to receive input and to provide output to a human.

In some instances, robots may at least partially resemble a human in appearance, for example having a head that resembles a human head, a torso that resembles a human torso, and/or appendages that resemble human appendages. Some of the humanoid appearing robots employ an artificial skin, for example one or more membranes of silicone.

Improvements in sensing, and in the appearance and operation of robots are commercially desirable.

### BRIEF SUMMARY

A flexible sensor array comprises a flexible mesh of islands and bridges, electrically conductive paths extending along the bridges between the islands, and modular panels that each carry one or more sensors and/or integrated circuits which are physically coupleable to the islands and communicatively coupleable to the electrically conductive paths. The flexible sensor array may be used with an artificial skin, for example joined to an artificial skin or even embedded in the artificial skin. Such may, for example, be used as an outer covering of a robot, for example a robot having a humanoid appearance.

### BRIEF DESCRIPTION OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and have been solely selected for ease of recognition in the drawings.

FIG. 1 is an isometric view of a flexible sensor array, according to at least one implementation.

FIG. 2 is a top isometric view of a modular sensor panel, according to at least one implementation.

FIG. 3 is a bottom isometric view of the modular sensor panel of FIG. 2, according to at least one implementation.

FIG. 4 is an isometric view of a flexible mesh and a processor communicatively coupled to the flexible mesh substrate, according to at least one implementation.

FIG. 5 is a top plan view of a portion of a flexible sensor array, better illustrating an island and adjoining bridges of the flexible sensor array, as well as couplers thereof, according to at least one implementation.

FIG. 6 is a top plan view of a portion of a flexible sensor array, better illustrating an island, adjoining bridges of the flexible sensor array and neighbor communication lines, as well as couplers thereof, according to at least one implementation.

FIG. 7 is a top plan view of a bridge of the flexible sensor array in a relaxed state or configuration and in a tensioned state or configuration, according to at least one implementation.

FIG. 8 is an isometric, partially cut-away view of a portion of an artificial skin layer employing a flexible sensor array, according to at least one implementation.

FIG. 9 is a cross section view of a portion of an artificial skin layer employing a flexible sensor array, according to at least one implementation, depressed by an object.

FIG. 10 is an electrical schematic diagram of a flexible sensor array, according to at least one implementation.

### DETAILED DESCRIPTION

In the following description, certain specific details are set forth in order to provide a thorough understanding of various disclosed implementations and embodiments. However, one skilled in the relevant art will recognize that the implementations and embodiments may be practiced without one or more of these specific details, or with other methods, components, structures, materials, etc. In other instances, well-known structures associated with skin-like sensor arrays (e.g., piezoelectric sensors, force sensitive materials, flexible PCB manufacturing, asynchronous electronic communication protocols) operable to provide human skin-like touch precision have not been shown or described in detail to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is, as “including, but not limited to.”

Reference throughout this specification to “in one implementation” or “in an implementation” or “one embodiment” or “an embodiment” means that a particular feature, structure or characteristic described in connection with the implementation or embodiment is included in at least one implementation or at least one embodiment. Thus, the appearances of the phrases “in one implementation” or “in an implementation” or “in one embodiment” or “in an embodiment” in various places throughout this specification are not necessarily all referring to the same implementation or embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

As used in this specification and the appended claims, “flexible”, “flexibly” and similar, refers to the ability of a material to bend, flex, twist, or otherwise deform to a functionally significant amount with little or no plastic deformation in at least one axis when a load is applied.

As used in this specification and the appended claims, “stretchable”, “stretchability”, “stretchably”, and similar, refers to the ability of a material to elongate to a functionally significant amount with little or no plastic deformation in at least one axis when a load is applied.

The headings and Abstract of the Disclosure provided herein are for convenience only and do not interpret the scope or meaning of the embodiments.

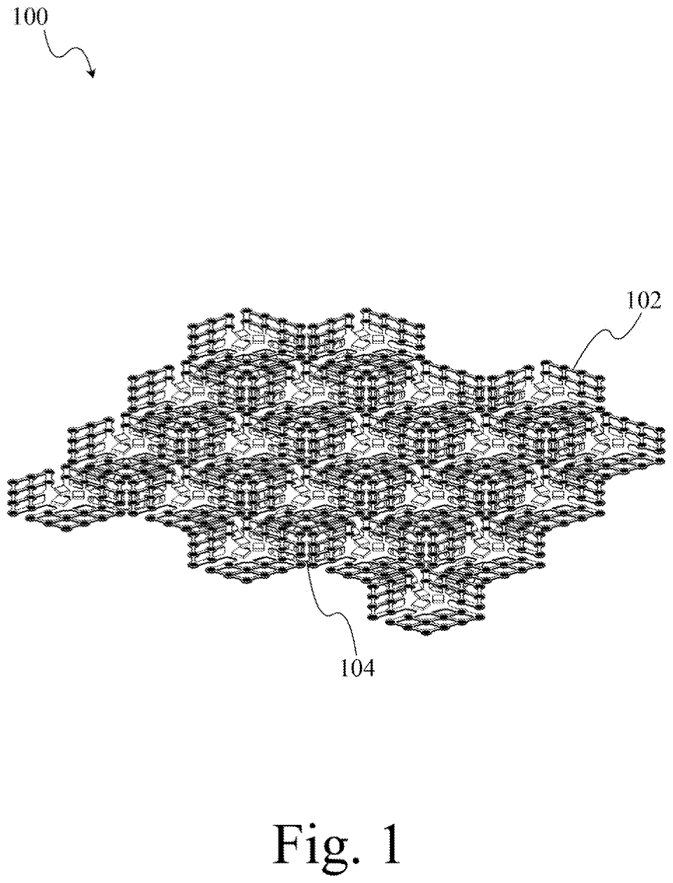

FIG. 1 shows a flexible sensor array 100 according to at least one illustrated implementation. The flexible sensor array 100 comprises a flexible mesh 104 and a plurality of modular sensor panels 102, the modular sensor panels 102 physically and communicatively coupled to respective locations on the flexible mesh 104. In at least some implementations, the modular sensor panels 102 are removable or detachably coupled to the flexible mesh 104 via couplers or connectors (described below).

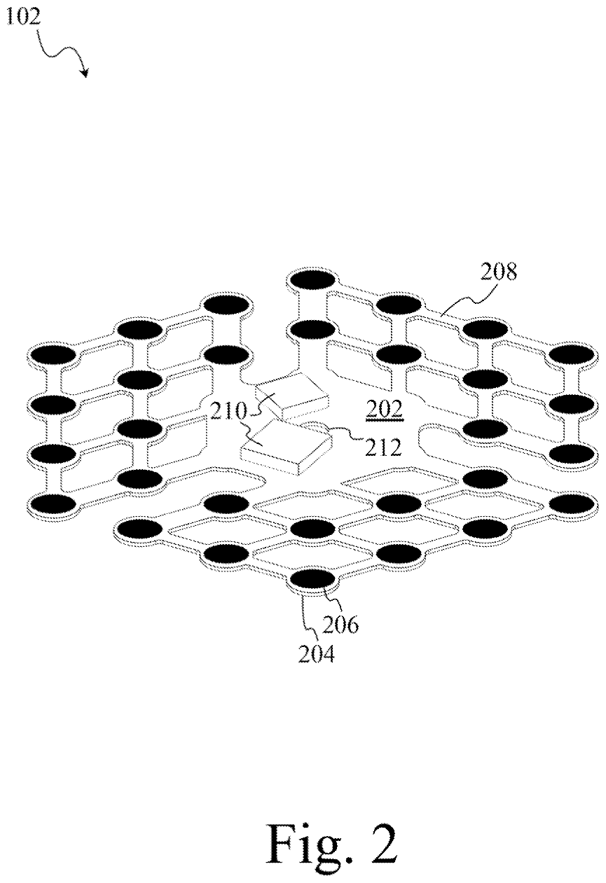

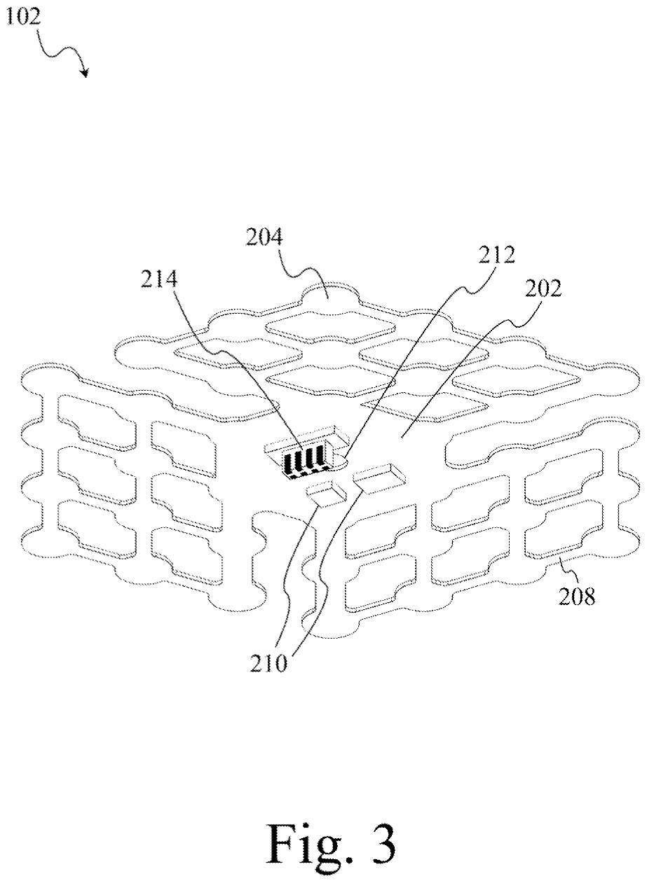

FIGS. 2 and 3 show a modular sensor panel 102 according to at least one illustrated implementation. The modular sensor panel 102 comprises a printed circuit board 202 and one or more sensors 206. The printed circuit board 202 may have a plurality of sensor areas 204. Each of the sensors 206 may be coupled or attached to a respective sensor area 204. The sensor(s) 206 may be attached, for example on a surface (denominated herein as a top side) of the printed circuit board 202.

The modular sensor panel 102 may also comprise one or more integrated circuits 210, each of the integrated circuits 210 may be coupled or attached to a respective location on the printed circuit board 202.

The printed circuit board 202 may take the form of a flexible printed circuit board, that bends or flexes without plastic deformation or destruction under an applied force, the applied force being a force that is anticipated to be applied during normal use, for instance the amount of force applied by a human finger pressing on the printed circuit board 202. In some implementations, the printed circuit board 202 may even take the form of a printed circuit board that stretches under an applied force (e.g., tension). For example, printed circuit board 202 may take the form of a printed circuit board with relatively few layers or that has a small thickness as compared to a lateral (e.g., length, width) dimension, to provide for the flexibility of the modular sensor panel 102. Additionally or alternatively, the sensor areas 204 may take the form of distinct islands, and the printed circuit board 202 of the modular sensor panel 200 may also include a plurality of sensor bridges 208 that couple the sensor areas 204 together, further enhancing the flexibility of the modular sensor panel 102.

Alternatively, the printed circuit board 202 may take the form of a rigid printed circuit board that does not bend or flex under an applied force, the applied force being a force anticipated to be applied during normal use, for instance the amount of force applied by a human finger pressing on the printed circuit board 202.

The printed circuit board 202 may comprise one or more layers of electrically insulative materials, for example Kapton or other polyimide layers which may enhance flexibility. The printed circuit board 202 may include one or more printed circuit traces and/or vias of electrically conductive materials, for example copper, beryllium copper, cupro-nickel, nickel, or silver epoxy. The printed circuit traces may be carried on an outer surface and/or on an inner layer of the printed circuit board 202. Vias may extend between opposed outer surfaces and/or between inner layers, and/or between an outer surface and an inner layer of the printed circuit board 202. Printed circuit traces and vias may carry signals and/or electrical power.

The integrated circuits 210 are physically coupled to the circuit board 202 and communicatively (e.g., signals, power) coupled to the plurality of sensors 206 through electrically conductive paths (e.g., electrically conductive traces) on the circuit board 202. Other implementations may have a fewer or greater number of integrated circuits 210 than illustration, and are operable to process, compress, and/or communicate the information generated or sensed or output by the sensors 206.

As best illustrated in FIG. 2, each of the modular sensor panels 102 has a respective physical coupler 212 that allows physical and/or mechanical coupling or connections to be made. In the illustrated implementation, the physical coupler 212 takes the form of a connection hole, female member or receptacle, which may for example be located at or proximate a center of the respective modular sensor panel 102. Other implementations may employ other types of mechanical couplers (e.g., fasteners, detents, snaps, magnets).

As best illustrated in FIG. 3 each of the modular sensor panels 102 includes a communications coupler 214 that allows communicatively coupling or connections (e.g., electrical coupling or connections) to be made. The communications coupler 214 may, for example, allow communications with external systems that are communicatively (e.g., electrically, inductively) coupled to the circuit board 202 and/or communicatively couples to the set of integrated circuits 210 through electrically conductive paths of the circuit board 202. Other implementations may have a different electrical coupler or connector (e.g., an electrical plug, electrical receptacle, or a set of contact electrical pins) for electrical communications (e.g., signals, power) with other systems. In some implementations, the physical coupler 212 and the communications coupler 214 may be integrated as a unitary coupler structure, for example a snap connector (e.g., cap or socket; stud or post) with electrically conductive material to provide one or more communications (e.g., signals, power) paths and which allows detachable press-fit or interference fit mechanical connections to be made. Thus, a cap or socket which mates with a stud or post may provide both mechanical and electrical connections.

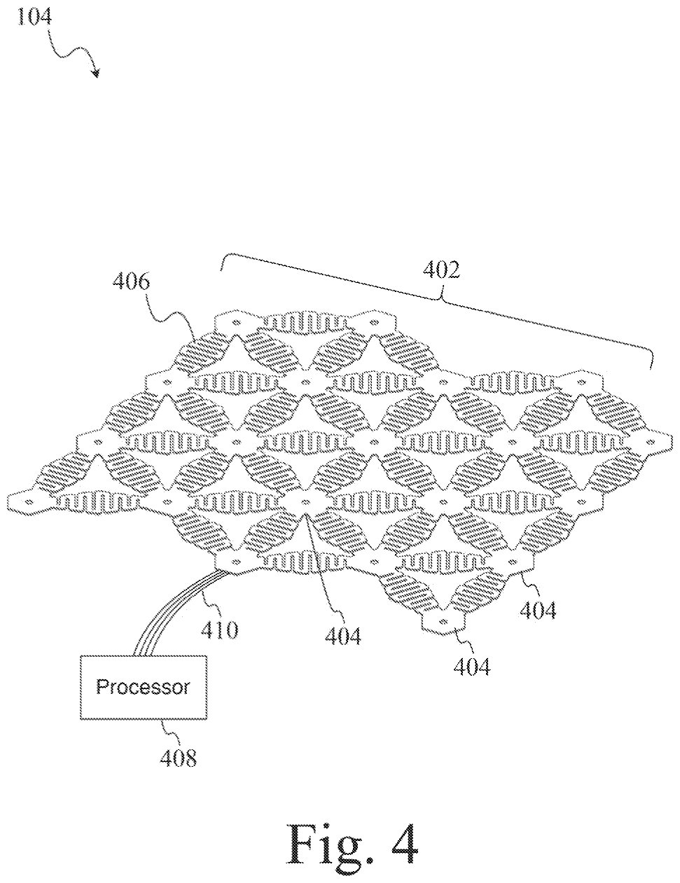

FIG. 4 shows a flexible mesh 104 according to at least one illustrated implementation. The flexible mesh 104 comprises a flexible printed circuit board 402, that bends or flexes without plastic deformation or destruction under an applied force, the applied force being a force that is anticipated to be applied during normal use, for instance the amount of force applied by a human finger pressing on the flexible printed circuit board 402. Preferably, the flexible printed circuit board 402 may even take the form of a printed circuit board that stretches under an applied force (e.g., tension).

The printed circuit board 402 may, for example, take the form of a printed circuit board with relatively few layers or that has a small thickness as compared to a lateral (e.g., length, width) dimension, to provide flexibility. The flexible printed circuit board 402 may comprise a set of islands 404 coupled together by a set of bridges 406. Each bridge 406 couples together two islands 404, each island 404 coupled at a respective end of the bridge 406. As best illustrated in FIG. 4, in at least some implementations, the islands 404 are positioned relative to one another as vertices along a triangular grid, with the bridges 406 positioned as line segments in the triangular grid. Some of the islands 404 (e.g., outermost corner islands 404) are directly coupled to two other islands 404, while some islands 404 are directly coupled to one, two, three, four, five, or even six other islands 404. Providing each island with connections to multiple other islands advantageously forms a highly redundant communications architecture. The redundancy allows some of the connection leads to fail without adversely affecting communications.

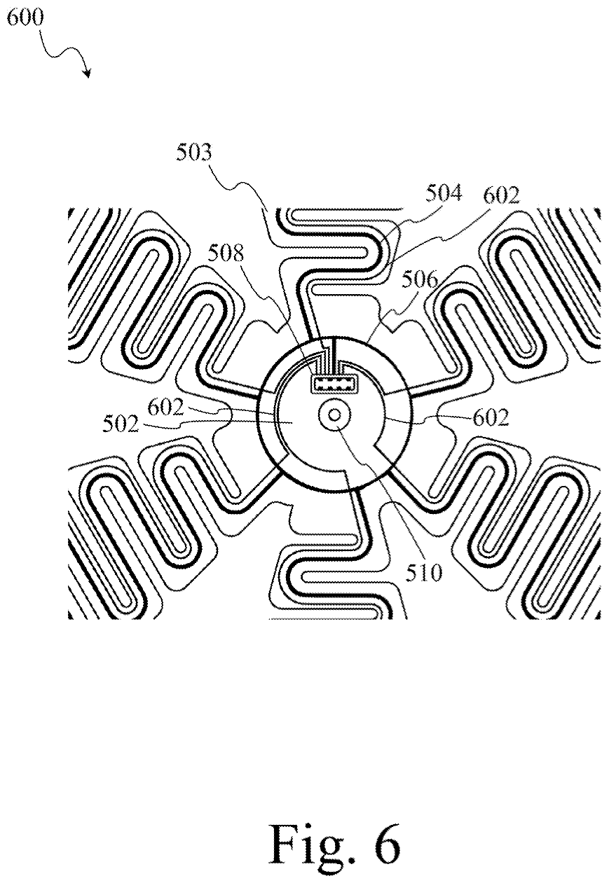

As illustrated in FIGS. 4, 5, 6, and 7, the bridges 406 each have a shape (e.g., convoluted, serpentine, zig-zag, and/or has flexures) such that when a force is applied along a longitudinal axis, the bridge 406 can flex, allowing for elongation of the bridge 406 along a longitudinal axis thereof (elongation best illustrated in FIG. 6).

The printed circuit board 402 may comprise one or more layers of electrically insulative materials, for example Kapton or other polyimide layers which may enhance flexibility. The printed circuit board 402 may include one or more printed circuit traces and/or vias of electrically conductive materials, for example copper, beryllium copper, cupro-nickel, nickel, or silver epoxy. The printed circuit traces may be carried on an outer surface and/or on an inner layer of the printed circuit board 402. Vias may extend between opposed outer surfaces and/or between inner layers, and/or between an outer surface and an inner layer of the printed circuit board 402. Printed circuit traces and vias may carry signals and/or electrical power.

Other implementations may have more or fewer islands and bridges in other tilings, such as square, rectangular, rhombic, hexagonal, or other, or in a non-tiling pattern. Other implementations may also have bridges and islands be separate structures coupled together through a set of mechanical and electrical couplers.

As also illustrated in FIG. 4, one or more processors 408 (only one shown) are physically and electrically coupled to the flexible mesh 400. For example, a set of electrical leads 408 of the flexible mesh 400 communicatively couple the processor to the islands 404, and subsequently to the sensors and/or integrated circuits 210 of the modular sensor panel 102, to allow signals and/or electrical power to be communicated therebetween. The processors 408 may take any form of logic circuit, for example microcontrollers, microprocessors, central processor units (CPUs), digital signal processors (DSPs), graphical processing units (GPUs), application specific integrated circuits (ASICs), field programmable gate arrays (FPGA), programmable logic controls (PLCs), communications chip, analog-to-digital converters (ADCs), any of which may be with or without memory.

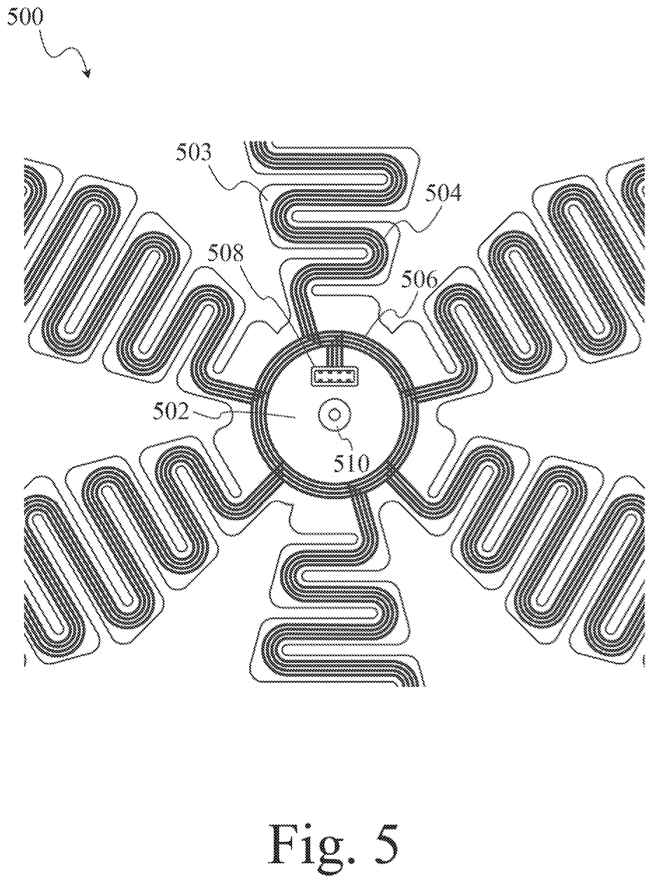

FIG. 5 shows a portion 500 of a flexible mesh (e.g., flexible mesh 104 (FIG. 1)) including one island 502 and a set of bridges 503 adjoining the island 502, according to at least one illustrated implementation. The island 502 is physically coupled to a set of six (6) bridges 503 at a first end of each of the six (6) bridges 503. Each bridge 503 further couples to other islands (not shown in FIG. 5 to reduce clutter) at a second end of the bridge 503. The island 502 may be made of various types of flexible circuit board materials (e.g., polyimide). The bridges 503 may also be made of various types of a flexible circuit board material (e.g., polyimide). In some implementations, the island 502 and the bridges 503 are formed as a unitary, single piece structure. In some implementations, the island 502 and the bridges 503 are formed as a unitary, single piece structure. In some other implementations, the islands 502 may be made of various types of non-flexible circuit board materials (e.g., FR-4) while the bridges 503 are made of various types of flexible circuit board materials (e.g., polyimide).

Each bridge 503 comprises a set of electrically conductive paths (e.g., electrically conductive circuit traces) 504 which in this implementation is a set of printed circuitry or conductive traces printed or otherwise formed on one or more layers of the flexible circuit board material. Each set of electrically conductive paths 504 is electrically coupled to a common electrical coupler or connector 506 such that each set of electrically conductive paths 504 is communicatively (e.g., electrically) coupled to every other set of electrically conductive paths 504 and the sets of electrically conductive paths form a common bus shared by the entire system.

Each island 502 comprises an electrical plug 508 that can receive an electrical coupler from a sensor module, for example as that shown in FIGS. 2 and 3, and is electrically coupled to the common electrical coupler or connector 506. Other implementations may have a different set of electrical couplers or connectors on the island 502 and sensor module such as electrical pads, pins, plugs, landings, or clips. The island 502 also comprises a mechanical connector 510 which, in this implementation, is a plastic piece designed to physically (e.g., mechanically) couple or connect to a complementary coupler or connector (e.g., hole in) of the modular sensor panel 102 (FIG. 1) and provide mechanical support to the modular sensor panel 102. Other implementations may have a single structure that connects the island 502 to a modular sensor panel 102 both electrically and mechanically.

FIG. 6 shows an alternative implementation of a portion 600 of a flexible mesh (e.g., flexible mesh 104 (FIG. 1)) including all of the structures in FIG. 5. Electrically conductive traces 504 and common electrical connector 506 are depicted as a single line in order to avoid clutter. The alternate implementation 600 additionally comprises a set of neighbor communication traces 602, each neighbor communication trace 602 running from the electrical plug 508, on the respective bridge 503, and to a respective neighboring island. The set of neighbor communication traces 602 allowing a device connected to the electrical connector 506 to map the presence and position of neighboring devices, allowing the entire mesh to automatically map the identity and position of each device connected to the mesh. The set of neighbor communication traces 602 may, for example, comprise electrically conductive traces, or alternatively electrically conductive wires with or without electrically insulative sheathing.

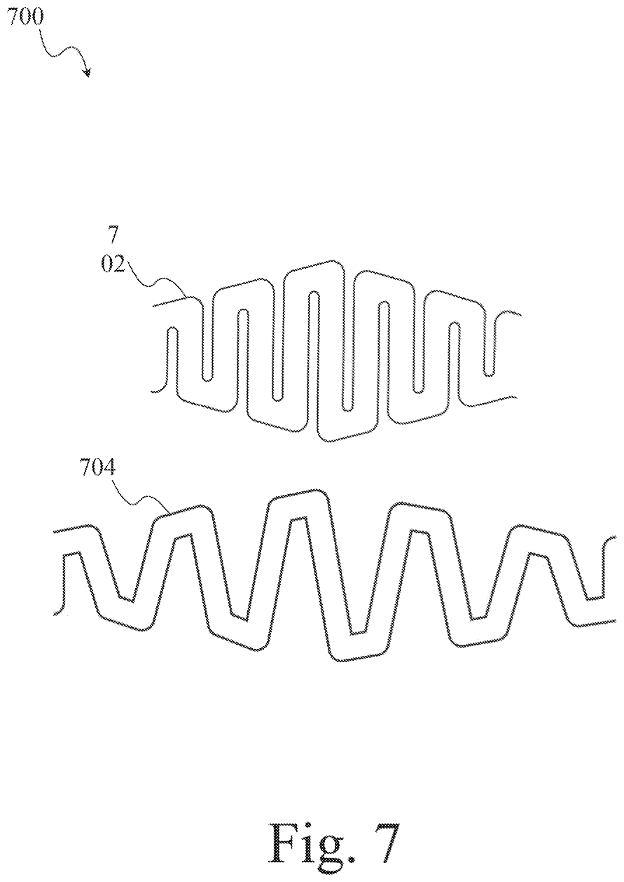

FIG. 7 shows a bridge 700 according to at least one illustrated implementation in both a relaxed or un-tensioned state or configuration 702 and in a stretched or tensioned state or configuration 704. When a force is applied to the bridge, for example along a longitudinal axis thereof, the bridge 700 may stretch or elongated. Stretching or elongation occurs even though the bridge 700 may not be made of a substantially stretchable material. Rather, the shape or profile of the bridge 700 provides the ability to stretch or elongate, or example when placed under tension. For example, the bridge 700 may have a convoluted or serpentine shape or profile, and/or may include one or more flexures), where elongation may result from the bridge 700 flexing at various corners of turns or undulations in the convoluted or serpentine shape or profile, and/or flexures. When a flexible mesh (e.g., flexible mesh 104 (FIG. 1)) includes multiple of these bridges 700, the flexible mesh can both elongate and flex along a variety of axes, even if the material that the flexible mesh is made of does not naturally stretch or elongate under tension prior to plastic deformation or destruction of same.

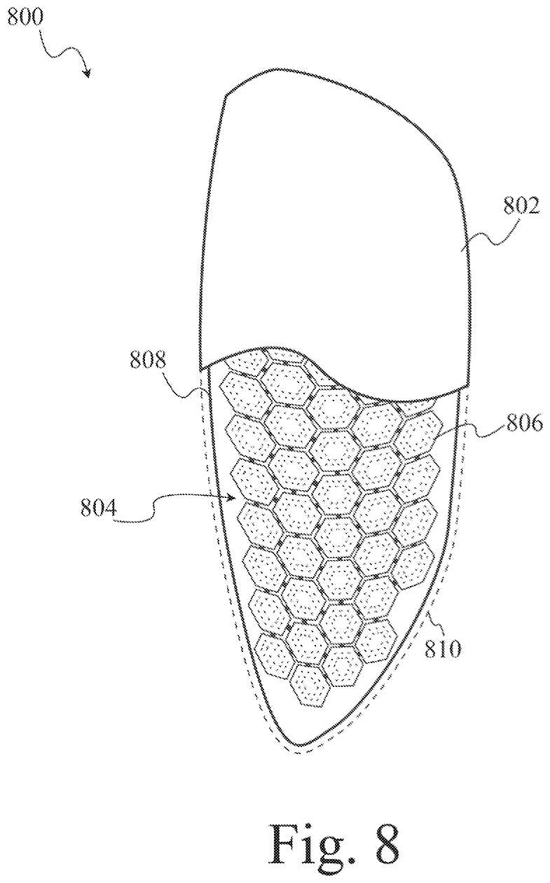

FIG. 8 shows a portion of an artificial skin 800 according to at least one illustrated implementation. The artificial skin 800 comprises a pliable, resilient, electrically insulating material 802 and a flexible sensor array 804. The flexible sensor array 804 may underlie the pliable, resilient, electrically insulating material 802. Thus, the pliable, resilient, electrically insulating material 802 may cover or overlie modular sensor panels 806 and flexible mesh 804. The pliable, resilient, electrically insulating material 802 may, for example, take the form of one or more sheets or membranes. The pliable, resilient, electrically insulating material 802 may, for example, comprise one or more sheets or membranes of silicone, to provide a soft, skin-like, texture.

The artificial skin 800 may optionally include a shell panel 808. The shell panel 808 includes structures that allow the artificial skin 800 to be attached to a portion of a robot, for example attached to a limb of a robot, for instance as shown in an example illustrated implementation. In some implementations the shell panel 808 may be a plastic panel with attachment features (e.g., holes, pins). A cut-away portion of the pliable, resilient, electrically insulating material 802 is indicated by broken-line 810. The sensors carried by the modular sensor panels 806 can detect and respond to pressure applied through the pliable, resilient, electrically insulating material 802 and relay corresponding sensor information to a processor of the flexible sensor array 100 (FIG. 1).

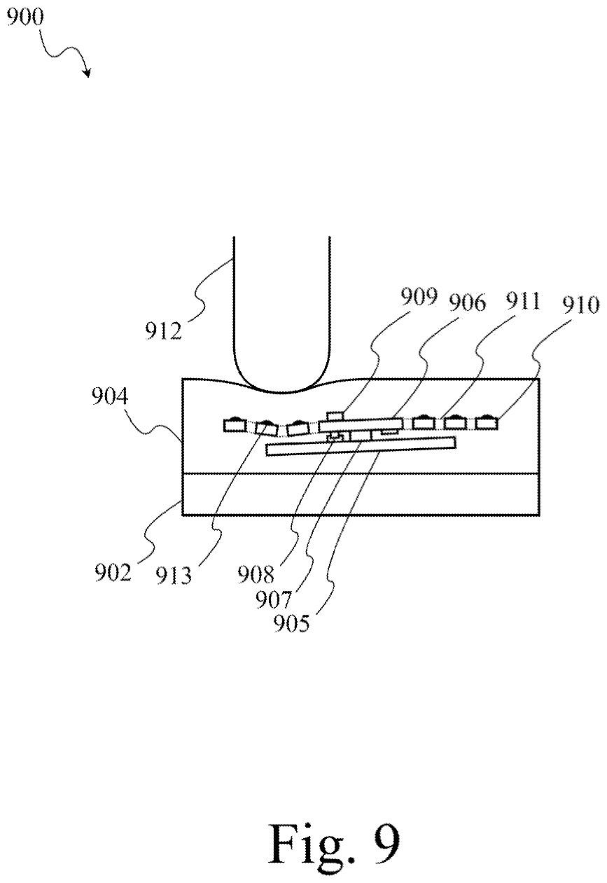

FIG. 9 shows cross section view of a portion of at least one implementation of an artificial skin 900 in a depressed state or configuration caused by an application of force thereto by a human finger. The artificial skin 900 comprises a shell panel 902 that is coupled to a layer of pliable, resilient, electrically insulating material 904. The pliable, resilient, electrically insulating material 904 may, for example, comprise a sheet or membrane of silicone, to provide a soft, skin-like, texture. Embedded within the insulating material 904 is a flexible mesh 905 such as flexible mesh 104 (only an island is visible for clarity). A sensor module 906 (such as sensor module 104) is embedded within the insulating material 904, mechanically coupled to the flexible mesh 905 through a mechanical coupler 907 (such as mechanical coupler 510) and communicatively coupled to the flexible mesh 905 through an electrical coupler 908 (such as electronic coupler 508). The sensor module 906 carries at least one integrated circuit 909 (such as integrated circuits 210) and comprises a set of sensor areas 910 and a set of sensor bridges 911 (such as sensor bridges 208) which are shown as a broken line, as they are not directly visible in this cross section view. Each sensor area 910 carries a force sensor 913, all force sensors 913 are communicatively coupled to the at least one integrated circuit 909, and the at least one integrated circuit 909 is communicatively coupled to a set of electrical signal lines on the flexible mesh 905 through the electrical coupler 908.

FIG. 9 further depicts an interacting object 912 pressing on the artificial skin 900. In this example, the interacting object 912 is a human finger but may be any solid semi-solid object that may provide a pressure or force on the artificial skin. The pressure of the interacting object 912 is transmitted through the layer of pliable, resilient, electrically insulating material 904, and causes the force sensors 913 positioned at or near the pressure location to detect a force. The sensor areas 910, sensor module 906, and flexible mesh 905 may also flex, bend, or otherwise morph to accommodate the pressure applied by the interacting object 912.

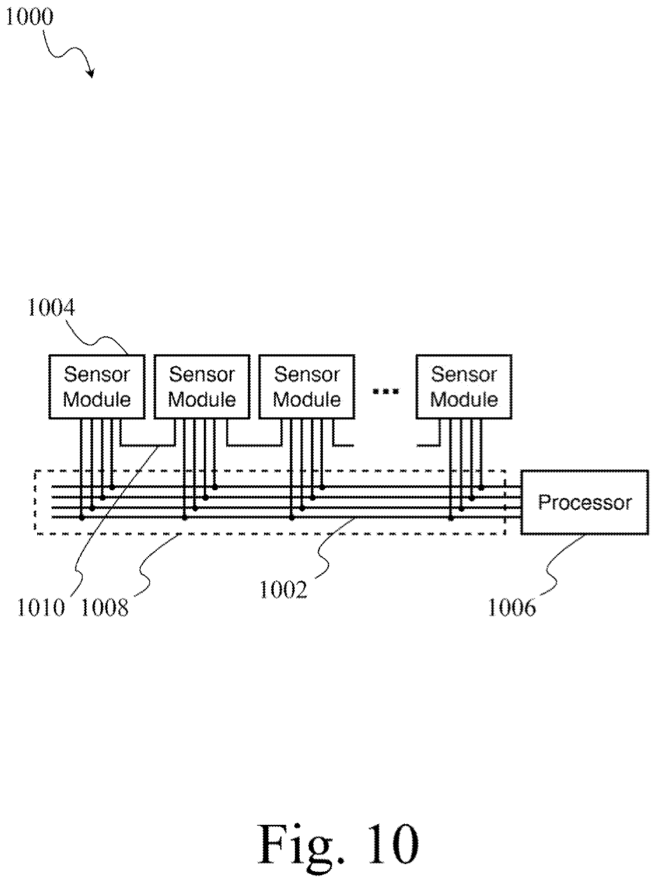

FIG. 10 shows a diagram circuit representation of a flexible sensor array 1000, according to at least one illustrated implementation. The flexible sensor array 1000 includes an communications bus 1002. The communications bus 1002 is shared by a plurality of modular sensor panels 1004 and a processor 1006. In this implementation, the communications bus is depicted to have four (4) paths, two for electric power and two for digital communications. Other implementations may have a fewer of greater number of distinct paths, depending on the communication protocol and the power requirements of the system. This implementation is designed to operate on an asynchronous CAN bus communication protocol, but other communication protocols may be used with small modifications to the bus structure such as I2C, SMBus, PMBus, EIA-485, SCSI-1/2, SCSI Ultra2, LIN, SIOX, DCC, I3C, X10, 1-Wire, TWI, and 10Base-2. The modular sensor panels 1004 may house a microcontroller, microprocessor, or logic circuit to communicate sensor information collected or sensed by the sensors from the modular sensor panels 1004 to the communications bus 1002. The processor 1006 may be a CPU, microcontroller, ASIC, FPGA, PLC, ADC, DAC, or other circuitry capable of communicating on the bus 1002. FIG. 10 additionally depicts a set of optional neighbor communication paths 1010 which communicatively coupled adjacent sensor modules 1004 and enables said adjacent sensor modules 1004 to communicate and map the layout and location of the sensor modules 1004. In the figure, in order to reduce clutter, each sensor modules 1004 is shown to have one or two neighbors, but in a variety of implementations, each sensor module 1004 may have as few as one or as many as 6 or more neighbors. The neighbor communication paths 1010 may take the form of electrically conductive traces, electrically conductive wires with or without electrically insulative sheathing, and/or optical fibers.

This application incorporates by reference the teachings of U.S. patent application 63/001,755 in its entirety. The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A flexible sensor array, comprising:
a flexible mesh, the flexible mesh comprising a plurality of islands and a plurality of bridges, wherein each respective bridge flexibly physically couples between a respective pair of islands and each respective island is flexibly physically coupled to at least two other islands via respective bridges, and wherein each respective island includes a respective coupler;
a plurality of electrically conductive paths, each respective electrically conductive path having at least two nodes, wherein each respective bridge carries at least a portion of at least one respective electrically conductive path with the nodes of the respective electrically conductive path located at respective ones of the pair of islands that are flexibly physically coupled by the respective bridge; and
a plurality of modular panels, each respective modular panel comprising a substrate, at least one sensor carried by the substrate, at least one integrated circuit, and a complementary coupler that is complementary to the respective couplers of the islands to at least physically couple the modular panel to a respective island with at least one electrical connection between the respective node at the island and the at least one sensor of the respective modular panel.

2. The flexible sensor array of claim 1 wherein each respective bridge comprises at least one dielectric layer, and wherein each respective electrically conductive path is a flexible electrically conductive trace carried by at least one bridge.

3. The flexible sensor array of claim 2 wherein each respective bridge has a plurality of flexures.

4. The flexible sensor array of claim 2 wherein each respective bridge comprises a plurality of layers of a dielectric having a serpentine profile.

5. The flexible sensor array of claim 1 wherein each of the modular panels is removably physically coupled to a respective one of the islands by a respective coupler.

6. The flexible sensor array of claim 1 wherein the substrate of each of the modular panels is a flexible substrate, and wherein the flexible substrate of each of the modular panels is bendable about at least one axis but is not stretchable.

7. The flexible sensor array of claim 1 wherein the substrate of each of the modular panels is a flexible substrate, and wherein the at least one electrical connection between the respective node at the island and the at least one sensor of the respective modular panel is an indirect electrical connection between the respective node and a contact of the at least one sensor via at least one electrically conductive path carried by the substrate of the modular panel.

8. The flexible sensor array of claim 1 wherein the substrate of each of the modular panels is a flexible substrate, and wherein the at least one electrical connection between the respective node at the island and the at least one sensor of the respective modular panel is a direct electrical connection between the respective node and a contact of the at least one sensor.

9. The flexible sensor array of claim 1 wherein the sensors include at least one of: a force sensor, a capacitive sensor, an inertial measurement sensor, or a temperature sensor.

10. The flexible sensor array of claim 1, further comprising:
at least one processor communicatively coupled to the respective integrated circuit of each respective modular panel by a set of the electrically conductive paths.

11. The flexible sensor array of claim 1 wherein the islands are tiled in a repeating pattern.

12. The flexible sensor array of claim 1 wherein the flexible sensor array underlies a pliable resilient electrically insulating material.

13. The flexible sensor array of claim 1 wherein the flexible sensor array is embedded in at least one pliable resilient electrically insulating membrane to form an artificial skin.

14. The flexible sensor array of claim 1 wherein the plurality of islands and the plurality of bridges are parts of a unitary, single piece substrate.

15. A flexible sensor array comprising:
a flexible mesh comprising a plurality of sensor panel coupling areas,
a plurality of electrically conductive elements each coupling a sensor panel coupling area to at least another sensor panel coupling area,
a plurality of sensor panels, each sensor panel comprising:
a set of sensors, the set of sensors comprising at least one of a force sensor, a capacitive sensor, an inertial measurement unit, or a temperature sensor,
an integrated circuit that electrically couples to the set of sensors, and
a mesh coupling mechanism that mechanically and electrically couples the sensor panel to a sensor panel coupling area on the flexible mesh,
and
an electronic controller or processor that electrically couples to the plurality of sensor panel coupling areas and communicates with the integrated circuit devices on the plurality of sensor panels.

16. The flexible sensor array of claim 15 wherein the plurality of sensor panel coupling areas are tiled on the flexible mesh in a triangular, a hexagonal, a rectangular or other regular tiling, and wherein each of the plurality of sensor panels has a geometric shape that matches the regular tiling of the sensor panel coupling areas.

17. The flexible sensor array of claim 15 wherein the flexible mesh comprises a set of sensor panel coupling areas to each of which at least one other one of the sensor panel coupling areas is fixed and a set of panel interconnects which flexibly couple adjacent sensor panel coupling areas.

18. The flexible sensor array of claim 17 wherein the set of sensor panel coupling areas and the set of panel interconnects are composed of a flexible printed circuit board material, and the plurality of electrically conductive elements are a set of printed circuitry on the flexible printed circuit board material.

19. The flexible sensor array of claim 15, further comprising:
an artificial skin composed of a soft insulating material covering the flexible mesh and the plurality of sensor panels on at least one side.

20. The flexible sensor array of claim 15, further comprising:
an artificial skin composed of a soft insulating material in which the flexible mesh and the plurality of sensor panels are imbedded.
